(19) United States
(12) Patent Application Publication
(10) Pub. No.: US 2017/0278726 A1
(43) Pub. Date: Sep. 28, 2017

(54) SUBSTRATE PROCESSING APPARATUS AND SUBSTRATE PROCESSING METHOD

(71) Applicant: SCREEN Holdings Co., Ltd., Kyoto (JP)

(72) Inventor: Katsuhiko MIYA, Kyoto (JP)

(21) Appl. No.: 15/468,246

(22) Filed: Mar. 24, 2017

(30) Foreign Application Priority Data
Mar. 25, 2016 (JP) 2016-061750

(51) Int. Cl. H01L 21/67; F26B 3/20

(52) U.S. Cl. CPC H01L 21/67034; H01L 21/67103; F26B 3/20

(57) ABSTRACT

A substrate processing apparatus comprises: a first chamber; a liquid film former which forms a liquid film P of a solution containing a sublimable substance having sublimability on a surface of a substrate in the first chamber; a second chamber 30 which receives the substrate W having the liquid film; a plate unit 311 provided in the second chamber such that the substrate W is placeable on an upper surface thereof; a temperature controller 312, 335 which controls a temperature of the upper surface of the plate unit 311 to a predetermined temperature; and a heater 322 which heats and sublimates the sublimable substance precipitated from the solution on the substrate W placed on the plate unit 311.

### CROSS REFERENCE TO RELATED APPLICATION

The disclosure of Japanese Patent Application No. 2016-061750 filed on Mar. 25, 2016 including specification, drawings and claims is incorporated herein by reference in its entirety.

### BACKGROUND OF THE INVENTION

1. Field of the Invention

This invention relates to a substrate processing technique for drying various substrates such as semiconductor substrates, glass substrates for photo mask, glass substrates for liquid crystal display, glass substrates for plasma display, substrates for FED (Field Emission Display), substrates for optical disc, substrates for magnetic disc and substrates for opto-magnetic disc, etc.

2. Description of the Related Art

In a manufacturing process of an electronic device such as a semiconductor device or a liquid crystal display device, it is generally carried out to process a substrate surface with a liquid and then dry the substrate by removing the liquid from the substrate surface. In particular, for the purpose of mainly preventing the destruction of a fine pattern formed on the substrate surface by surface tension of the liquid, there is a technique for filling a sublimable substance between pattern elements and sublimating the sublimable substance after evaporating a liquid component.

For example, in a technique described in JP2012-243869A, a solution containing a sublimable substance is supplied to a substrate surface and pattern concave parts are primarily filled with the sublimable substance by evaporating a solvent component in the solution. By heating up the substrate to a temperature higher than a sublimation temperature of the sublimable substance, the sublimable substance is removed from the substrate.

In the conventional technique described in the above literature, a process from a rinsing step of supplying a rinsing liquid to the substrate to a solvent drying step of evaporating the solvent from the solution containing the sublimable substance is performed in a single processing unit. Further, it is described as a modification in this prior art literature to perform a process until a sublimable substance removing step of sublimating the sublimable substance by the same processing unit.

However, in such a process, the step of evaporating the solvent by increasing the temperature of the substrate after a processing by the liquid having a relatively low temperature is performed for each substrate. Thus, the deterioration of a tact time and a reduction of energy efficiency due to such a temperature increasing and cooling cycle become problematic. Particularly, in the case of drying the solvent and removing the sublimable substance by different units in the above conventional technique, the substrate temperature decreases during a movement between the units, wherefore the above problems become more significant.

### SUMMARY OF THE INVENTION

The invention was developed in view of the above problem and an object thereof is to provide a technique capable of processing with a short tact time and high energy efficiency in a substrate processing technique for sublimating a sublimable substance after a solvent component is evaporated from a solution containing the sublimable substance on a substrate surface.

To achieve the above object, a substrate processing apparatus according to one aspect of the invention includes a first chamber, a liquid film former for forming a liquid film of a solution containing a sublimable substance having sublimability on a surface of a substrate in the first chamber, a second chamber for receiving the substrate having the liquid film formed thereon, a plate unit provided in the second chamber such that the substrate is placeable on an upper surface thereof, a temperature controller for controlling a temperature of the upper surface of the plate unit to a predetermined temperature and a heater for heating and sublimating the sublimable substance precipitated from the solution on the substrate placed on the plate unit.

According to such a configuration, a processing of forming the liquid film of the solution on the substrate, that is, a processing requiring no heating is performed in the first chamber. On the other hand, a processing of evaporating a solvent from the liquid film and sublimating the sublimable substance, i.e. requiring heating is performed in the second chamber. Therefore, the substrate needs not be increased in temperature in the first chamber. Further, in the second chamber, the evaporation of the solvent in the solution proceeds by placing the substrate having the liquid film on the plate unit increased in temperature. Thus, the plate unit has only to be kept at a temperature necessary and sufficient to evaporate the solvent and the temperature of the plate unit needs not be increased and decreased for the progress of a processing process.

It is sufficient for the heater to supply only heat energy for sublimating the precipitated sublimable substance from the substrate already warmed to such an extent to evaporate the solvent to the sublimable substance after the evaporation of the solvent. At this time, the substrate needs not necessarily be heated. Thus, the amount of heat supplied by the heater and a heating period can be reduced. Further, since a temperature increase of the substrate can be suppressed as compared to a configuration in which heat energy from the plate unit is transferred to the sublimable substance via the substrate, damage to the substrate by heat is also avoided.

As just described, in the invention, the processing of forming the liquid film on the substrate and the heating processing of evaporating the solvent from the liquid film and sublimating the precipitated sublimable substance are performed in different chambers. Further, in the invention, heating for evaporating the solvent from the solution constituting the liquid film and heating for sublimating the precipitated sublimable substance are performed by different entities. Thus, a cycle of increasing and decreasing the temperature of the plate unit is essentially unnecessary. Therefore, there is no waiting time for a temperature change and a heat energy loss is small. Further, the temperature of the substrate does not decrease between the evaporation of the solvent and the sublimation of the sublimable substance. Thus, given heat energy can be more efficiently utilized for the processings. Specifically, the processings can be performed with excellent energy efficiency.

Further, to achieve the above object, a substrate processing apparatus according to another aspect of the invention includes a chamber for receiving a substrate having a liquid film of a solution containing a sublimable substance having sublimability formed on a surface thereof, a plate unit provided in the chamber such that the substrate is placeable on an upper surface thereof, a temperature controller for controlling a temperature of the upper surface of the plate unit to a predetermined temperature and a heater for heating and sublimating the sublimable substance precipitated from the solution on the substrate placed on the plate unit.

A technique for forming liquid films on substrate surfaces using various liquids and a technique for conveying a substrate while keeping a formed liquid film have already been put to practical use. From this point, the invention can be carried out, for example, using a substrate having a liquid film of a solution containing a sublimable substance formed thereon by the existing technique as a processing object. Also by such a configuration, processings can be performed with a short tact time and excellent energy efficiency as in the above invention.

Further, to achieve the above object, a substrate processing method according to one aspect of the invention executes forming a liquid film by a solution containing a sublimable substance having sublimability on a surface of a substrate in a first chamber, conveying the substrate having the liquid film to a second chamber and placing the substrate on a plate unit which is provided in the second chamber and has an upper surface temperature-controlled to a predetermined temperature, evaporating a solvent from the liquid film on the substrate placed on the plate unit and precipitating the sublimable substance in the second chamber, and heating and sublimating the sublimable substance precipitated in the second chamber.

Also by such a configuration, processings can be performed with a short tact time and excellent energy efficiency as in the above invention.

As described above, according to the invention, liquid film formation on the substrate and heating for evaporating the solvent from the solution and sublimating the precipitated sublimable substance are performed in different chambers. Further, a heating entity for evaporating the solvent from the solution constituting the liquid film and a heating entity for sublimating the precipitated sublimable substance are different. Thus, the deterioration of a tact time for a temperature change and a reduction of energy efficiency can be avoided.

The above and further objects and novel features of the invention will more fully appear from the following detailed description when the same is read in connection with the accompanying drawing. It is to be expressly understood, however, that the drawing is for purpose of illustration only and is not intended as a definition of the limits of the invention.

### BRIEF DESCRIPTION OF THE DRAWINGS

FIG. 1 is a plan view showing a layout of one embodiment of a substrate processing system according to the invention.

FIGS. 2A and 2B are diagrams showing the configuration of the wet processing unit.

FIG. 3 is a flow chart outlining the wet processing by the wet processing unit.

FIGS. 4A and 4B are diagrams showing the configuration of the drying unit.

FIG. 5 is a flow chart outlining a drying process by the first drying unit.

FIG. 6 is a timing chart showing a series of processings realized by the cooperation of the wet processing unit and the drying unit.

FIGS. 7A and 7B are diagrams showing another configuration of the drying unit.

FIG. 8 is a flow chart outlining a drying process by the second drying unit.

### DETAILED DESCRIPTION OF THE PREFERRED EMBODIMENTS

Hereinafter, an embodiment of the invention is described with reference to the drawings, taking a substrate processing apparatus used for the processing of semiconductor substrates as an example. It should be noted that the invention can be applied also to the processing of various substrates such as glass substrates for liquid crystal display without being limited to the processing of semiconductor substrates. In the following description, substrates mean various substrates such as semiconductor substrates, glass substrates for photo mask, glass substrates for liquid crystal display, glass substrates for plasma display, substrates for FED (Field Emission Display), substrates for optical disc, substrates for magnetic disc and substrates for opto-magnetic disc.

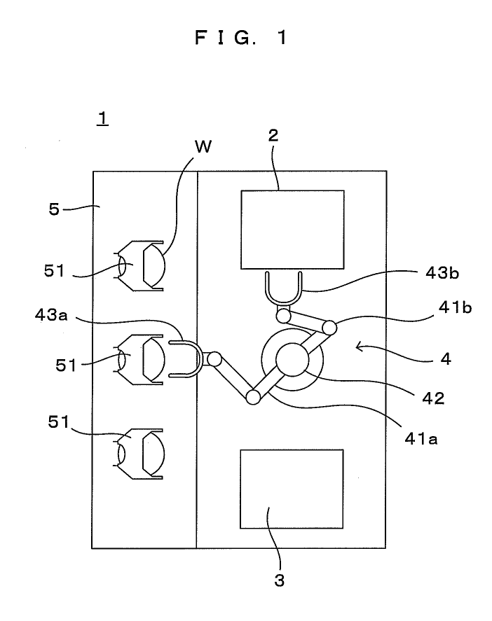

FIG. 1 is a plan view showing a layout of one embodiment of a substrate processing system according to the invention. This substrate processing system 1 is a processing system for drying a semiconductor substrate (hereinafter, merely referred to as a “substrate”) W, which will become a material of a semiconductor device, after the substrate W is wet-processed by a processing liquid and is, for example, used in a development processing of the substrate W. The substrate processing system 1 includes a wet processing unit 2, a drying unit 3, a conveying unit 4 and a substrate station 5. Note that a plurality of each of these units may be provided. In this case, the number of the wet processing units 2 and that of the drying units 3 need not necessarily be equal.

A plurality of cassettes 51 for accommodating substrates W to be processed can be placed on the substrate station 5. In an example of FIG. 1, three cassettes 51 are placed. The substrate W is taken out from each cassette 51 by the conveying unit 4, successively conveyed to the wet processing unit 2 and the drying unit 3 to be subjected to predetermined processings and, then, finally accommodated into the cassette 51.

In the conveying unit 4, base end parts of two folding arms 41a, 41b are mounted on a unit body 42 rotatably about a vertical axis. An axis perpendicular to the plane of FIG. 1 is the vertical axis. A hand 43a capable of supporting the substrate W from below and a hand 43b capable of supporting the substrate W from below are respectively provided on a tip part of the folding arm 41a and a tip part of the folding arm 41b rotatably about a vertical axis. An unillustrated driving mechanism causes the folding arms 41a, 41b to extend and contract and turn independently of each other relative to the unit body 42 and causes the hands 43a, 43b to rotate relative to the folding arms 41a, 41b. As just described, the conveying unit 4 can simultaneously convey two substrates W by driving two substrate conveyors independently of each other.

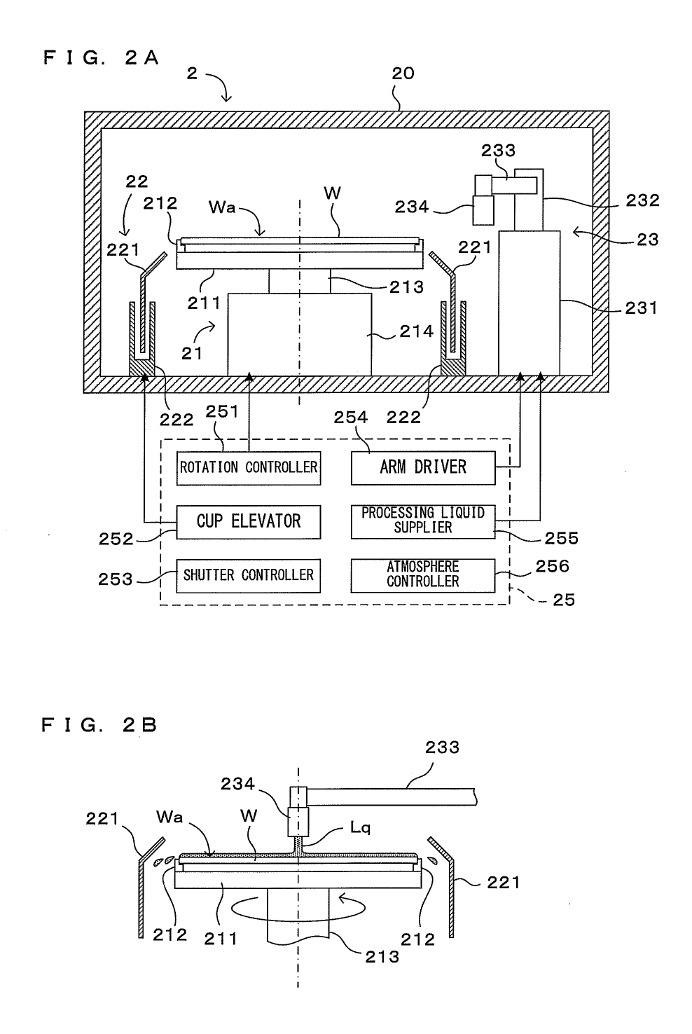

FIGS. 2A and 2B are diagrams showing the configuration of the wet processing unit. Specifically, FIG. 2A is a side sectional view showing an internal structure of the wet processing unit 2 and FIG. 2B is a diagram showing the operation of a main part of the wet processing unit 2. The wet processing unit 2 performs wet processings such as a chemical processing and a rinse processing on the substrate W taken out from the cassette 51 by the conveying unit 4. Many techniques are known as such wet processings using various processing liquids and processing apparatuses therefor and appropriate ones of those known techniques can be applied also in this embodiment. Accordingly, in this specification, the configuration and operation of the unit are briefly described and detailed processing contents are not described.

As shown in FIG. 2A, the wet processing unit 2 includes a substrate holder 21, a splash guard 22 and a liquid supplier 23 provided in a wet processing chamber 20, and a controller 25. The substrate holder 21 includes a disc-shaped spin chuck 211 having a diameter substantially equal to that of the substrate W and a plurality of chuck pins 212 are provided on a peripheral edge part of the spin chuck 211. The spin chuck 211 can hold the substrate W in a horizontal posture with the substrate W separated from the upper surface thereof by the chuck pins 212 supporting the substrate W while being held in contact with the peripheral edge part of the substrate W.

The spin chuck 211 is supported by a rotary support shaft 213 extending downward from a central part of the lower surface of the spin chuck 211 such that an upper surface is horizontal. The rotary support shaft 213 is rotatably supported by a rotating mechanism 214 mounted on a bottom part of the wet processing chamber 20. The rotating mechanism 214 includes an unillustrated built-in rotary motor and the rotary motor is controlled by a rotation controller 251 of the controller 25. The rotary motor rotates in response to a control command from the rotation controller 251, whereby the spin chuck 211 directly connected to the rotary support shaft 213 rotates about a vertical axis indicated by a dashed-dotted line. In FIGS. 2A and 2B, an up-down direction is a vertical direction. In this way, the substrate W is rotated about the vertical axis while being kept in the horizontal posture.

The splash guard 22 is provided to laterally surround the substrate holder 21. The splash guard 22 includes a substantially tubular cup 221 provided to cover a peripheral edge part of the spin chuck 211 and a liquid receiver 222 provided below an outer peripheral part of the cup 221. The cup 221 is driven to move upward and downward by a cup elevator 252 provided in the controller 25. The cup elevator 252 drives the cup 221 to move upward and downward between a lower position where an upper end part of the cup 221 is located below the peripheral edge part of the substrate W held on the spin chuck 211 as shown in FIG. 2A and an upper position where the upper end part of the cup 221 is located above the peripheral edge part of the substrate W as shown in FIG. 2B.

When the cup 221 is at the lower position, the substrate W held on the spin chuck 211 is exposed to the outside of the cup 221 as shown in FIG. 2A. Thus, the cup 221 is prevented from standing as a hindrance, for example, when the substrate W is carried onto and out from the spin chuck 211.

Meanwhile, when the cup 221 is at the upper position, the cup 211 surrounds the peripheral edge part of the substrate W held on the spin chuck 211 as shown in FIG. 2B. In this way, a processing liquid spun off from the peripheral edge part of the substrate W in the wet processing to be described later can be prevented from scattering in the chamber 20 and reliably recovered. Specifically, liquid droplets of the processing liquid spun off from the peripheral edge part of the substrate W by the rotation of the substrate W adhere to the inner wall of the cup 221 and flows downwardly. The downwardly flowing processing liquid is collected and recovered by the liquid receiver 222 arranged below the cup 221. Cups may be concentrically provided in a plurality of stages to individually recover a plurality of processing liquids.

The liquid supplier 23 is structured such that a nozzle 234 is attached to the tip of an arm 233 horizontally extending from a rotary support shaft 232 rotatably provided on a base 231 fixed to the wet processing chamber 20. The rotary support shaft 232 is controlled by an arm driver 254 provided in the controller 25. The arm 233 swings by the rotation of the rotary support shaft 232 in response to a control command from the arm driver 254. In this way, the nozzle 234 on the tip of the arm 234 moves between a retracted position shown in FIG. 2A where the nozzle 234 is laterally retracted from a position above the substrate W and a processing position shown in FIG. 2B where the nozzle 234 is above the substrate W.

The nozzle 234 is connected to a processing liquid supplier 255 provided in the controller 25. The processing liquid supplier 255 supplies various liquids such as chemicals including an etching solution, a rinsing liquid and pure water as the processing liquids to the nozzle 234. As shown in FIG. 2B, by supplying a processing liquid Lq from the processing liquid supplier 255 with the nozzle 234 located at the processing position above the substrate W, the processing liquid Lq is discharged from the nozzle 234 toward the substrate W. Particularly, by discharging the processing liquid Lq from the nozzle 234 positioned above a center of rotation of the substrate W while rotating the substrate W at a suitable rotation speed, an upper surface Wa of the substrate W can be entirely covered with a liquid film. A plurality of liquid suppliers 23 may be provided in the wet processing chamber 20 to cope with a plurality of kinds of processing liquids.

Besides, the controller 25 is provided with a shutter controller 253, an atmosphere controller 256 and the like. The shutter controller 253 opens and closes an unillustrated shutter provided on a side surface of the wet processing chamber 20 and used to transfer the substrate W into and from the wet processing chamber 20. The atmosphere controller 256 controls an atmosphere in the chamber by introducing appropriate gas into the wet processing chamber 20 and discharging the gas in the wet processing chamber 20. Since general configurations in substrate processing apparatuses can be used as the configurations of these, these are not described in detail.

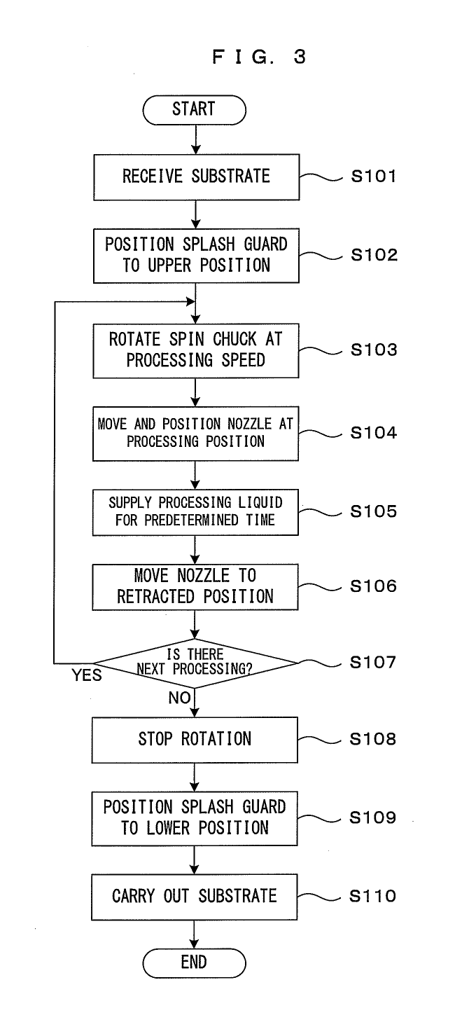

FIG. 3 is a flow chart outlining the wet processing by the wet processing unit. This processing is realized by the controller 25 executing a processing recipe prepared in advance and controlling each component of the wet processing unit 2 to perform a predetermined operation. First, the substrate W is received into the wet processing unit 2 (Step S101). Specifically, the unillustrated shutter of the wet processing chamber 20 is opened by the shutter controller 253. Then, the conveying unit 4 carries one substrate W taken out from the cassette 51 into the wet processing chamber 20 and places it on the spin chuck 211. After the chuck pins 212 hold the peripheral edge part of the substrate W and the conveying unit 4 is retracted, the shutter is closed, thereby completing the reception of the substrate W.

Subsequently, the cup controller 252 moves and positions the cup 221 of the splash guard 22 from the lower position to the upper position (Step S102). Then, the rotation controller 251 rotates the spin chuck 211 at a predetermined rotation speed determined by the processing recipe (Step S103). In this way, the substrate W rotates at a rotation speed (processing speed) corresponding to the purpose of the wet processing.

Then, the nozzle 234 is moved to and positioned at the processing position by the arm driver 254 (Step S104) and the processing liquid supplied from the processing liquid supplier 255 is discharged from the nozzle 234 for a predetermined time (Step S105). In this way, the processing liquid is supplied to the substrate W and the substrate W is wet-processed. After the supply of the processing liquid is stopped, the nozzle 234 is moved to the retracted position (Step S106).

When another wet processing should be further processed (YES in Step S107), a return is made to Step S103 and the new wet processing is performed after the rotation speed of the substrate W and the type of the processing liquid are changed if necessary. In the absence of the next processing (NO in Step S107), the rotation of the substrate W is stopped (Step S108). After the cup 221 of the splash guard 22 is returned to the lower position (Step S109), the substrate W is carried out (Step S110). Specifically, the shutter is opened by the shutter controller 253 and the conveying unit 4 holds the substrate W on the spin chuck 211 and carries the substrate W out of the chamber. In this way, the wet processing by the wet processing unit 2 is finished.

The substrate W being carried out is wet with the processing liquid. For example, if the rotation speed of the substrate W is appropriately set during the processing, the entire upper surface Wa of the substrate W is covered with the liquid film. As already known, a thickness of the liquid film can be adjusted by the rotation speed according to the magnitude of surface tension of the processing liquid. The substrate W can be conveyed with the upper surface Wa covered with the liquid film by properly setting the thickness of the liquid film and conveying the substrate W while keeping the substrate W in the horizontal posture. Since the hand 43a, 43b of the conveying unit 4 supports the lower surface of the substrate W, the substrate W can be conveyed without the liquid film formed on the upper surface Wa being touched. As described later, the substrate W carried out from the wet processing unit 2 in the wet processing of this embodiment has the upper surface Wa thereof covered with the liquid film of a solution containing a sublimable substance.

The substrate W carried out in a wet state as just described is dried by the drying unit 3. Specifically, the drying unit 3 has a function of removing the processing liquid remaining on and adhering to the substrate W being carried thereinto in the horizontal posture and drying the substrate W. Although two modes of the drying unit 3 are disclosed in this specification, the configuration and operation of a drying unit 3a of a first mode are described here.

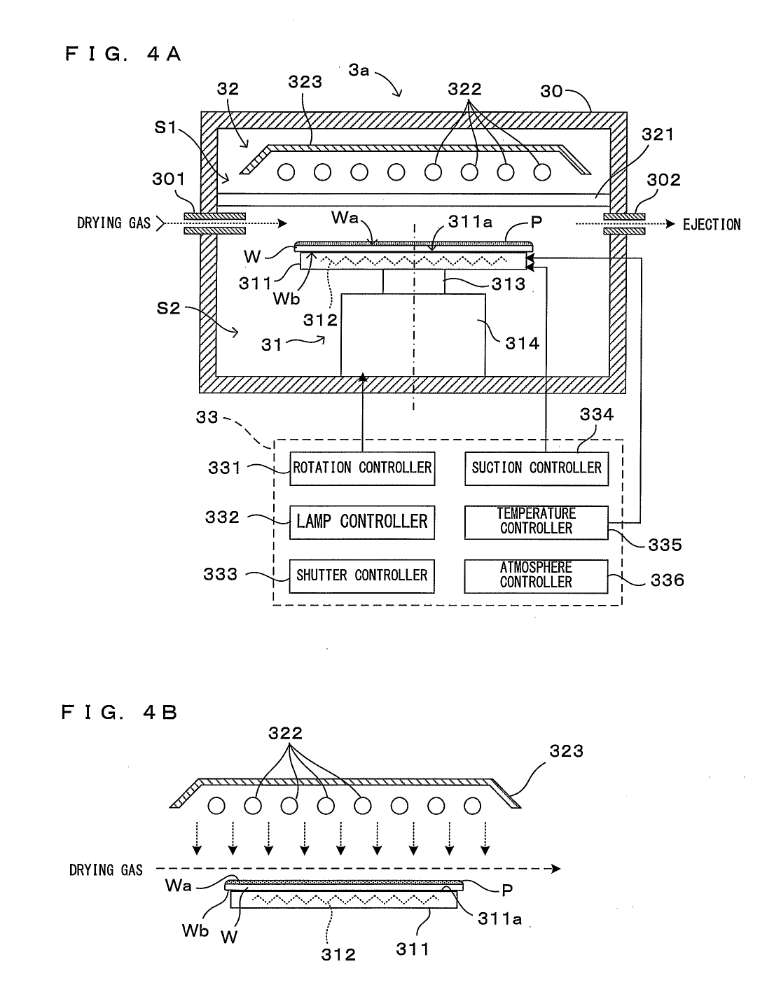

FIGS. 4A and 4B are diagrams showing the configuration of the drying unit. Specifically, FIG. 4A is a side sectional view showing an internal structure of the drying unit 3a of the first mode and FIG. 4B is a diagram showing the operation of a main part of the drying unit 3a. As shown in FIG. 4A, the drying unit 3a of the first mode includes a substrate holder 31 and a lamp heater 32 provided in a drying chamber 30 and a controller 33.

The substrate holder 31 includes a disc-shaped supporting plate 311 having a diameter slightly smaller than the substrate W and can hold the substrate W in a horizontal posture by holding an upper surface 311a of the supporting plate 311 in close contact with a lower surface Wb of the substrate W being carried into. Although not shown, the upper surface 311a of the supporting plate 311 is provided with suction holes or suction grooves and a negative pressure from a suction controller 334 of the controller 33 is supplied to the suction holes or suction grooves. In this way, the substrate holder 31 can firmly hold the substrate W in the horizontal posture with the lower surface Wb of the substrate W held in close contact with the upper surface 311a of the supporting plate 311.

A heater 312 is built in the supporting plate 311 and controlled by a temperature controller 335 of the controller 33. The temperature controller 335 increases the temperature of the supporting plate 311 and keeps the temperature of the upper surface of the supporting plate 311 at a predetermined temperature by causing the heater 312 to generate heat. Thus, when the substrate W is placed on the supporting plate 311, heat of the supporting plate 311 is transferred to the substrate W to warm the substrate W. Note that a configuration for increasing the temperature of the supporting plate is arbitrary without being limited to the one with a built-in heater. For example, the supporting plate itself may be formed of a resistive element or the supporting plate may generate heat by induction heating. Further, it is sufficient to keep the upper surface of the supporting plate at the predetermined temperature and the entire supporting plate needs not have the same temperature.

The supporting plate 311 is supported by a rotary support shaft 313 extending downward from a central part of the lower surface of the supporting plate 311 such that the upper surface 311a is horizontal. The rotary support shaft 313 is rotatably supported by a rotating mechanism 314 mounted on a bottom part of the drying chamber 30. The rotating mechanism 314 includes an unillustrated built-in rotary motor and the rotary motor is controlled by a rotation controller 331 of the controller 33. The rotary motor rotates in response to a control command from the rotation controller 331, whereby the supporting plate 331 directly connected to the rotary support shaft 313 rotates about a vertical axis indicated by a dashed-dotted line. In FIGS. 4A and 4B, an up-down direction is a vertical direction. In this way, the substrate W is rotated about the vertical axis while being kept in the horizontal posture.

The lamp heater 32 is arranged above the substrate W supported on the substrate holder 31. Specifically, an upper space S1 in the chamber 30 is partitioned from a lower space S2 by a transparent partition wall 321, for example, made of quartz glass. For example, a plurality of xenon lamps as heating lamps 322 are aligned in a horizontal direction in the upper space S1. A reflector 323 is arranged above the heating lamp 322. The heating lamps 322 are controlled by a lamp controller 332 of the controller 33. When the respective lamps 322 are turned on all at once in response to a control command from the lamp controller 332, light including many infrared components and emitted from the lamps 322 is irradiated toward the upper surface Wa of the substrate W directly or by being reflected by the reflector 323 as shown in FIG. 4B. The temperature of the upper surface Wa of the substrate W can be suddenly increased by such a configuration.

Further, a gas inlet port 301 is provided on a side surface of the drying chamber 30. The gas inlet port 301 communicates with an atmosphere controller 336 provided in the controller 33. The atmosphere controller 336 supplies dry gas as drying promoting fluid for promoting the drying of the substrate W into the drying chamber 30 via the gas inlet port 301 if necessary. High-temperature nitrogen gas increased to an appropriate temperature can be, for example, used as the drying gas. By using the drying gas increased in temperature, the evaporation of a solvent and the sublimable substance can be promoted by keeping the substrate W in a high-temperature environment. Further, by quickly removing these vaporized components from the vicinity of the substrate W, drying is further promoted.

A gas discharge port 302 is provided on a side of the side surface of the drying chamber 30 opposite to the gas inlet port 301 across the substrate holder 31. The gas discharge port 302 communicates with the atmosphere controller 336 and the atmosphere controller 336 ejects an atmosphere in the drying chamber 30 through the gas discharge port 302 if necessary. The arrangement positions of the gas inlet port 301 and the gas discharge port 302 are determined such that the drying gas introduced through the gas inlet port 301 flows along the upper surface Wa of the substrate W held on the substrate holder 31 and is ejected from the gas discharge port 302.

Besides, the controller 33 is provided with a shutter controller 333 for opening and closing an unillustrated shutter provided on the side surface of the wet drying chamber 30 and used to transfer the substrate W into and from the wet drying chamber 30. Since a general configuration in substrate processing apparatuses can be used as such a configuration, this is not described in detail.

The drying unit 3a configured as described above is preferable to perform a so-called sublimation drying processing. The sublimation drying processing is to sublimate the sublimable substance and remove the sublimable substance from the surface of the substrate W after a liquid component is removed with the sublimable substance adhering to the surface of the substrate W. A sublimation drying technique is a drying method capable of preventing the destruction of a pattern due to surface tension of a liquid, for example, when a substrate having the fine concave and convex pattern formed on a surface is dried by removing a liquid component.

This drying unit 3a is for receiving the substrate W having a liquid film P by the solution containing the sublimable substance formed on the upper surface Wa and drying the substrate W. Specifically, the sublimable substance is precipitated on the upper surface Wa of the substrate W by first evaporating a solvent component from the liquid film P formed on the upper surface Wa of the received substrate W. Subsequently, the precipitated sublimable substance is sublimated and removed. By filling the sublimable substance in concave parts of the pattern, the destruction of the pattern when the liquid component is evaporated can be prevented. The principle of such a sublimation drying technique is not described since being already known. For example, the description of the aforementioned prior art literature can be used as reference. In this embodiment, it is assumed to handle the substrate W such that a pattern forming surface out of principal surfaces of the substrate W is the upper surface Wa.

The following materials can be, for example, used as materials of the liquid film for realizing sublimation drying, but the materials are arbitrary without being limited to these. For example, naphthalene, ammonium fluorosilicate, various thermally decomposable polymers and the like can be used as the sublimable substance. Further, pure water, DIW (deionized water) and IPA (isopropyl alcohol) liquid at normal temperature or solvents, which are mixtures of these and capable of dissolving the sublimable substance with a high solubility, can be appropriately selected and used as the solvent for dissolving the sublimable substance. A technical idea of this embodiment does not depend on the types of the materials used and various materials can be used by adjusting processing conditions such as temperature and time.

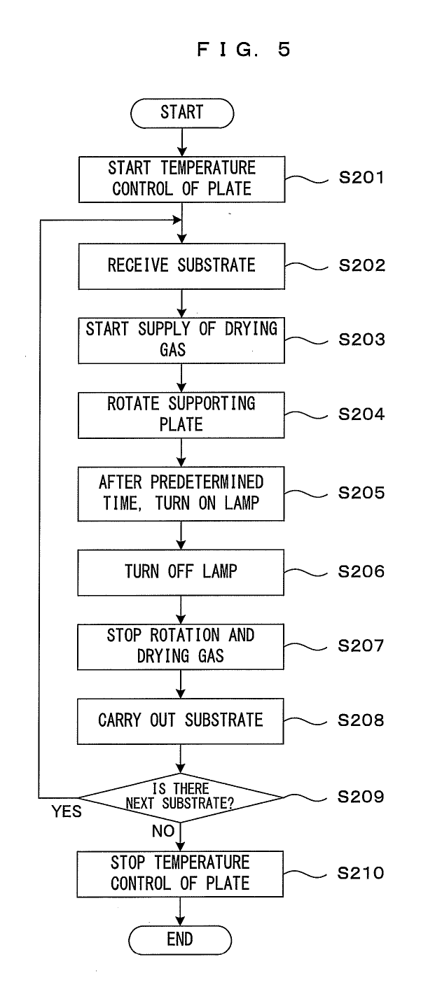

FIG. 5 is a flow chart outlining a drying process by the first drying unit. This processing is realized by the controller 33 executing a processing recipe prepared in advance and controlling each component of the first drying unit 3a to perform a predetermined operation. The drying unit 3a receives the substrate W having the liquid film P of the solution containing the sublimable substance formed on the upper surface Wa and conveyed in the horizontal posture by the conveying unit 4 (Step S202). Prior to reception, a temperature control of the supporting plate 311 by the temperature controller 335, more precisely a temperature control of the heater 312 is started (Step S201).

A control target temperature of the heater 312 is determined according to the types of the sublimable substance and the solvent. In the case of using the materials of the above examples, the control target temperature can be, for example, set such that the temperature of the upper surface of the supporting plate 311 reaches 180° C.

In receiving the substrate W, the unillustrated shutter of the drying chamber 30 is opened by the shutter controller 333. The conveying unit 4 carries the substrate W carried out from the wet processing chamber 20 into the drying chamber 30 and places the substrate W on the supporting plate 311. At this time, it is desirable that the temperature of the upper surface of the supporting plate 311 has already reached a predetermined temperature. The suction controller 334 supplies a negative pressure to the suction holes or suction grooves provided in the upper surface 311a of the supporting plate 311, whereby the substrate W is sucked and held by the supporting plate 311. By closing the shutter after the conveying unit 4 is retracted, the reception of the substrate W is completed.

Subsequently, the supply of the drying gas from the atmosphere controller 336 into the drying chamber 30 is started (Step S203). Further, the substrate W is rotated at a predetermined rotation speed by the rotation controller 331 rotating the supporting plate 311 (Step S204). Since the supporting plate 311 is increased in temperature in advance, the substrate W is warmed by the supporting plate 311 when being placed on the supporting plate 311, thereby promoting the evaporation of the solvent component from the liquid film P formed on the upper surface Wa of the substrate W. Specifically, the placement of the substrate W on the heated supporting plate 311 itself corresponds to the start of a step of evaporating the solvent. The sublimable substance precipitated as the solvent is evaporated fills up the concave parts of the pattern to prevent the destruction of the pattern due to surface tension of the solvent.

After the elapse of a predetermined time necessary to substantially completely evaporate the solvent component, the heating lamps 322 are turned on (Step S205). At this time, the upper surface Wa of the substrate W is covered with the precipitated sublimable substance and light irradiated from the heating lamps 322 heats the sublimable substance to promote the sublimation. Note that it is difficult to strictly control the temperature of the upper surface of the substrate W by lamp heating. However, since the amount of heat sufficient to sublimate the sublimable substance has only to be given for the purpose of the processing, a particularly strict temperature control is not necessary.

The lamps are turned off at a timing when the sublimable substance remaining on the substrate W is substantially entirely removed (Step S206). Then, the rotation of the substrate W and the supply of the drying gas are stopped (Step S207) and the drying processing for one substrate W is finished. The processed substrate W is carried out (Step S208). Specifically, the shutter is opened by the shutter controller 333 and the conveying unit 4 holds the substrate W on the supporting plate 311 released from suction and holding and carries it out from the chamber.

If there is the next substrate to be processed (YES in Step S209), a return is made to Step S202 and a processing similar to the above is repeated. If there is no more substrate to be processed (NO in Step S209), the temperature control of the supporting plate 311 is stopped (Step S210) and the drying processing is finished.

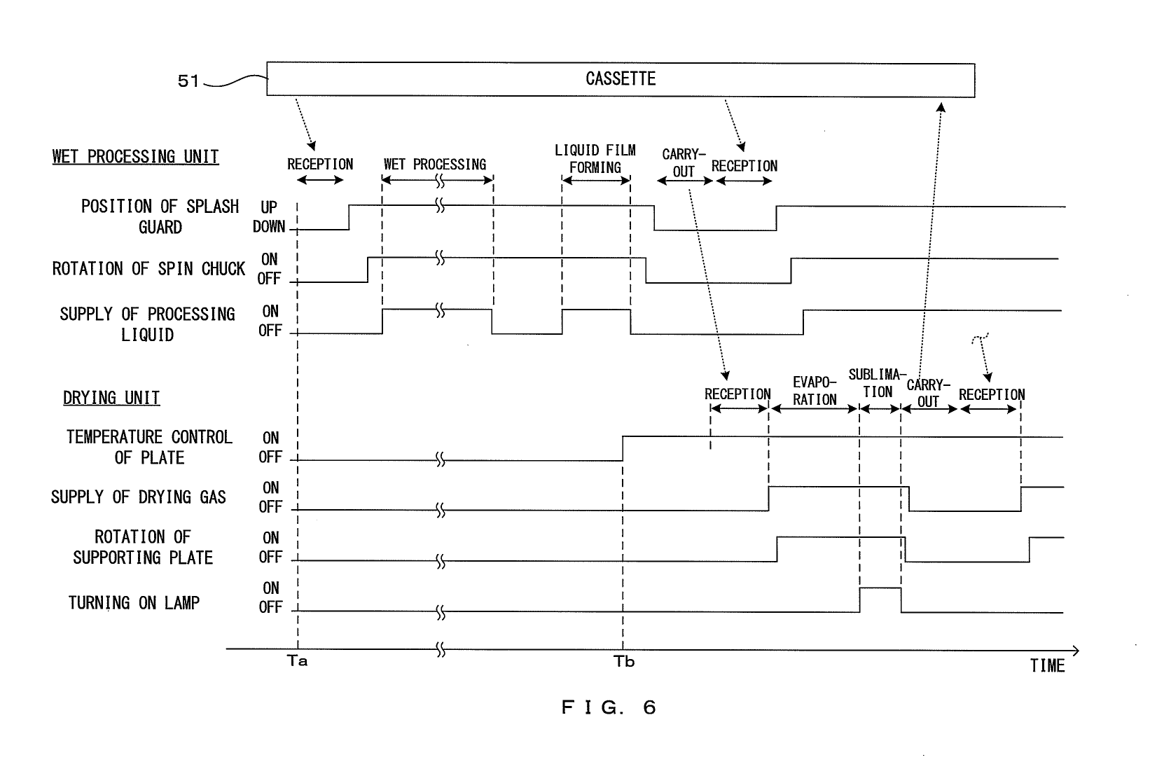

FIG. 6 is a timing chart showing a series of processings realized by the cooperation of the wet processing unit and the drying unit. At time Ta, the conveying unit 4 takes one substrate W from the cassette 51. This substrate W is conveyed to the wet processing unit 2 and received into the wet processing chamber 20 (“reception” step). Thereafter, the cup 221 of the splash guard 22 is moved from the lower position to the upper position and the spin chuck 211 starts rotating. Then, the appropriate processing liquid is continuously or intermittently supplied from the nozzle 234 positioned at the processing position to perform the wet processing (“wet processing” step). During this time, the rotation speed of the spin chuck 211 may be changed and the type of the processing liquid may be switched.

Finally, in the wet processing unit 2, the liquid film P by the solution containing the sublimable substance is formed on the upper surface Wa of the substrate W (“liquid film formation” step). When the liquid film P is formed, the rotation of the spin chuck 211 is stopped. After the cup 221 of the splash guard 22 is returned to the lower position, the substrate W is carried out from the wet processing chamber 20 by the conveying unit 4 (“carry-out” step). In the wet processing unit 2 from which the substrate W has been carried out, each component is returned to an initial state so that a new substrate W can be received and successively processed (new “reception” step).

The substrate W carried out from the wet processing unit 2 and having the liquid film P formed on the upper surface Wa is conveyed to the drying unit 3 and received into the drying chamber 30 (“reception” step). At time Tb prior to reception, the temperature control of the supporting plate 311 is started. Thus, at a point of time when the substrate W is carried into the drying chamber 30 and placed on the supporting plate 311, the supporting plate 311 has been already increased in temperature. Thus, the evaporation of the solvent component in the liquid film P is started when the substrate W is placed on the supporting plate 311 (“evaporation” step). By supplying the drying gas and rotating the supporting plate 311 at this time, evaporation can uniformly proceed on the substrate W.

After this state is maintained for a while so that the solvent sufficiently evaporates, the heating lamps 322 are turned on for a predetermined time. This causes the sublimable substance precipitated on the upper surface Wa of the substrate W by the evaporation of the solvent to be heated to vaporize and sublimate (“sublimation” step). When the lamps are turned off and the supply of the drying gas and the rotation of the supporting plate 311 are stopped, the substrate W is taken out from the drying chamber 30 and accommodated into the cassette 51 by the conveying unit 4 (“carry-out” step).

Since the temperature control of the supporting plate 311 is continued also after the sublimation step is finished, a new substrate W can be immediately received and processed (new “reception” step). Since the supporting plate 311 on which the substrate W is to be placed is heated in advance in the drying unit 3 as just described, the evaporation step can be performed without delay after the substrate W is carried into. By additionally turning on the heating lamps 322 in a final stage of the evaporation step, a transfer is immediately made from the evaporation step to the sublimation step.

As just described, there is no process of changing the control target temperature during the processing and there is no waiting time associated with a temperature change. Thus, in the drying unit 3, the drying processing can be started without delay after the substrate is received and a time required for the drying processing is short. Thus, the drying processing of the substrate W can be performed with a short tact time and excellent energy efficiency. If there is a difference in tact time between the wet processing by the wet processing unit 2 and the drying processing by the drying unit 3, an operation rate of each unit can be enhanced to improve processing efficiency by making the numbers of the wet processing units 2 and the drying units 3 incorporated into the substrate processing system 1 different.

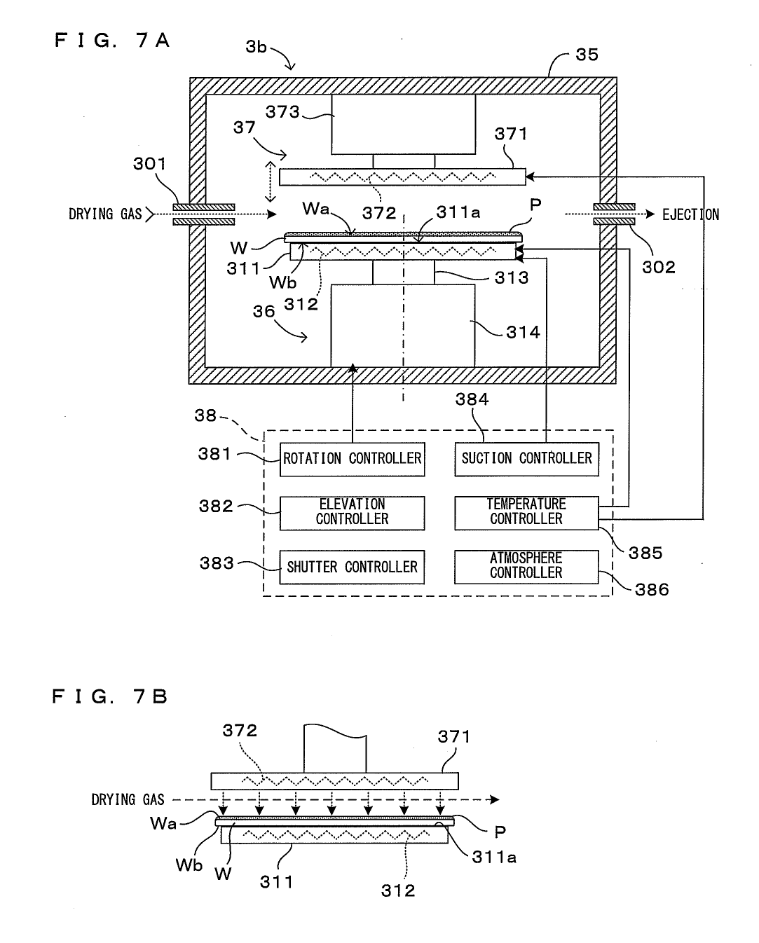

FIGS. 7A and 7B are diagrams showing another configuration of the drying unit. Specifically, FIG. 7A is a side sectional view showing an internal structure of a second drying unit 3b and FIG. 7B is a diagram showing the operation of a main part of the drying unit 3b. As shown in FIG. 7A, the drying unit 3b of a second mode includes a substrate holder 36 and an upper plate unit 37 provided in a drying chamber 35 and a controller 38. Note that, in FIGS. 7A and 7B, the same components as those of the drying unit 3a of the first mode shown in FIG. 4A are identified by the same reference signs and not described in detail.

The drying chamber 35 and the substrate holder 36 in the drying unit 3b respectively have the same configurations as the drying chamber 30 and the substrate holder 31 in the drying unit 3a. Further, functions of a rotation controller 381, a shutter controller 383, a suction controller 384 and an atmosphere controller 386 of the controller 38 are the same as the corresponding components in the drying unit 3a.

On the other hand, in the drying unit 3b, the upper plate unit 37 is provided in the drying chamber 35 instead of the lamp heater 32 of the drying unit 3a. The upper plate unit 37 includes an upper plate 371 having a built-in heater 372 and an elevating mechanism 373 for moving the upper plate 371 upward and downward. The elevating mechanism 373 is controlled by an elevation controller 382 provided in the controller 38. The elevating mechanism 373 moves the upper plate 371 between a separated position shown in FIG. 7A where the upper plate 371 is separated upwardly from a supporting plate 311 and a proximate position shown in FIG. 7B where the upper plate 371 is proximate to and right above the supporting plate 371 in response to a control command from the elevation controller 382.

Further, a temperature controller 385 provided in the controller 38 controls the upper surface of the supporting plate 311 to a predetermined temperature by controlling a built-in heater 312 of the supporting plate 311 similarly to the aforementioned drying unit 3a. Further, the temperature controller 385 keeps the lower surface of the upper plate 371 at a temperature higher than the upper surface of the supporting plate 311 by controlling the heater 372 built in the upper plate 371. The upper surface Wa of the substrate W placed on the supporting plate 311 is instantly heated by radiation heat from the upper plate 371 with the upper plate 371 positioned at the proximate position where the upper plate 371 is proximately facing the supporting plate 311 as shown in FIG. 7B. In this way, the sublimable substance adhering to the upper surface Wa of the substrate W can be sublimated in a short time as by lamp heating in the drying unit 3a.

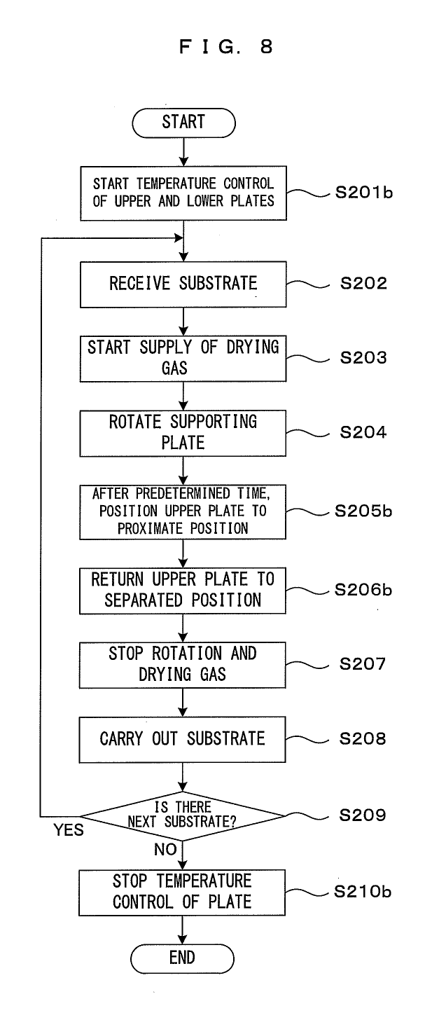

FIG. 8 is a flow chart outlining a drying process by the second drying unit. This processing is realized by the controller 38 executing a processing recipe prepared in advance and controlling each component of the second drying unit 3b to perform a predetermined operation. Note that most of processing contents are common to the processings in the first drying unit 3a. Accordingly, processings common to the processings shown in the flow chart of FIG. 5 are denoted by the same Step numbers and not described, and points of difference between the both are mainly described.

In the second drying unit 3b, temperature controls of the upper and lower plates, i.e. the upper plate 371 and the supporting plate 311 are started prior to the reception of the substrate W in Step S201b replacing Step S201 of FIG. 5. As described above, the upper plate 371 is controlled to a temperature higher than the supporting plate 311 and can be, for example, set at 450° C.

Further, the elevating mechanism 373 controlled by the elevation controller 382 moves the upper plate 371 positioned at the separated position in advance to the proximate position right above the substrate W in Step S205b replacing Step S205 of FIG. 5. In this way, infrared rays radiated from the heated upper plate 371 are irradiated to the upper surface Wa of the substrate W in a concentrated manner and the sublimable substance adhering to the upper surface Wa are instantly heated and sublimated. Specifically, a movement of the upper plate 371 to the proximate position in the second drying unit 3b is alternative to the turning-on of the heating lamps 322 in the first drying unit 3a.

Furthermore, the upper plate 371 is returned from the proximate position to the separated position by the elevating mechanism 373 in Step S206b replacing Step S206 of FIG. 5. This is to weaken the heating of the substrate W by distancing the upper plate 371 and corresponds to the turning-off of the heating lamps 322 in the first drying unit 3a. Further, the temperature control of the upper plate 371 is also stopped together with that of the supporting plate 311 when the processing is finished (Step S210b replacing Step S210).

As just described, the sublimable substance on the substrate W is sublimated in the second drying unit 3b by bringing the upper plate 371 heated in advance closer to the upper surface Wa of the substrate W instead of turning on the heating lamps 322 in the first drying unit 3a. Specifically, a basic principle of the drying processing is the same although a heat source for heating and sublimating the sublimable substance adhering to the substrate W is different between the first and second drying units 3a, 3b.

Specifically, in these drying processings, the substrate W having the liquid film P containing the sublimable substance formed thereof is received and placed on the supporting plate 311 increased in temperature. In this way, the solvent component in the liquid film P is evaporated while the sublimable substance is precipitated. Thus, the liquid component can be removed while the destruction of the pattern is prevented. Further, the supporting plate 311 is increased in temperature in advance. Thus, as compared to a method in which a temperature increase is started with the substrate W placed, a waiting time until the supporting plate is warmed can be shortened.

The supporting plate 311 has only to be kept at a substantially fixed temperature and it is not necessary to increase or decrease the temperature during the processing. Thus, the supporting plate 311 can be, for example, formed of a material having a large heat capacity and a high heat storage property, and heat energy necessary to keep the temperature of the supporting plate 311 can be reduced. Particularly, since the substrate W is held in close contact with the supporting plate 311 and warmed by heat conduction, a loss by heat released into space is small and energy efficiency is also excellent.

The vicinity of the upper surface Wa of the substrate W having the sublimable substance adhering thereto is selectively heated by the heat source different from the one for heating the supporting plate 311 to evaporate the solvent component. By doing so, the sublimable substance is instantly heated and sublimated. By heating the sublimable substance by strong radiation as in the above example, quick heating free from a time delay due to the heat capacities of the supporting plate 311 and the substrate W is possible, for example, as compared to a method for sublimating the sublimable substance by increasing the temperature of the supporting plate. In this way, the sublimable substance can be removed from the substrate W within a short time. Further, damage caused by heating up the substrate W can be prevented. Furthermore, the temperatures of the substrate W and the supporting plate 311 need not be increased and heat energy has only to be given within a short time until the sublimable substance is removed from the substrate W. Thus, the consumption of heat energy can be further reduced and energy efficiency can be enhanced.

Further, the wet processing associated with the supply of the liquid and the drying processing including the heating process, but not associated with the supply of the liquid are performed in different chambers. This enables each chamber to be dedicatedly structured for the processing content. For example, components having no heat resistance can be used in the wet processing chamber 20. Further, piping for liquid supply and components for waste liquid processing need not be provided, for example, in the drying chamber 30. By optimizing the chamber structures according to the processing contents, processing efficiency can be improved and apparatus cost can be reduced.

As described above, the substrate processing system 1 of the above embodiment can be regarded to correspond to a “substrate processing apparatus” of the invention. At this time, the wet processing unit 2 corresponds to a “liquid film former” of the invention. The substrate holder 21 and the liquid supplier 23 respectively function as a “holder” and a “liquid supplier” of the invention. Further, the wet processing chamber 20 functions as a “first chamber” of the invention. Further, the conveying unit 4 functions as a “conveyor” of the invention.

Further, the supporting plate 311 functions as a “plate unit” of the invention. Further, the heater 312 and the temperature controller 335 integrally function as a “temperature controller” of the invention. Further, in the drying unit 3a, the drying chamber 30 and the heating lamps 322 respectively function as a “second chamber” and a “heater” of the invention. On the other hand, in the drying unit 3b, the drying chamber 35 functions as the “second chamber” of the invention. The upper plate 371 and the heater 372 integrally function as the “heater” of the invention.

Further, the drying unit 3 (3a, 3b) can also be regarded to correspond to the “substrate processing apparatus” of the invention. At this time, the drying chambers 30, 35 function as a “chamber” of the invention and the supporting plate 311 functions as the “plate unit” of the invention. The heater 312 and the temperature controller 335 integrally function as the “temperature controller” of the invention. Further, in the drying unit 3a, the heating lamps 322 function as the “heater” of the invention. On the other hand, in the drying unit 3b, the upper plate 371 and the heater 372 integrally function as the “heater” of the invention.

Further, in the above embodiment, the atmosphere controllers 336, 386 function as an “ejector” of the invention. Further, the rotating mechanism 314 functions as a “rotator” of the invention. Further, in the drying unit 3b of the above embodiment, the upper plate 371 functions as a “heat radiating member” of the invention, whereas the elevating mechanism 373 functions as a “moving mechanism” of the invention.

Note that the invention is not limited to the above embodiment and various changes other than those described above can be made without departing from the gist of the invention. For example, in the substrate processing system 1 of the above embodiment, the wet processing unit 2, the drying unit 3 and the conveying unit 4 are integrated. However, these units may be configured as independent different apparatuses and cooperate. Further, an appropriate conveyor such as an external conveyor robot or a manipulator may be utilized instead of the conveying unit.

Further, for example, the drying units 3a, 3b of the above embodiment heat the sublimable substance on the substrate W by radiation heat from the heating lamps 322 or the upper plate 371. Specifically, the “heater” of the invention irradiates infrared rays as “electromagnetic waves” to the substrate W. Instead of this, electromagnetic waves having another wavelength such as microwaves for directly heating the sublimable substance may be, for example, used. For example, laser heating may be used as long as it does not damage substrates. Further, the sublimable substance may be heated by supplying hot air onto the substrate W.

Further, the types, the processing temperatures and the like of the sublimable substance and the solvent in the above embodiment are merely some examples of the invention. By optimizing the processing conditions according to substances used, the technical idea of the invention can be applied to various combinations of a sublimable substance and a solvent.

As the specific embodiment has been illustrated and described above, the heater may be, for example, configured to irradiate an electromagnetic wave for increasing the temperature of the sublimable substance toward the plate unit from above the plate unit in the substrate processing apparatus of the invention. According to such a configuration, the substrate surface or the sublimable substance precipitated on this surface can be directly heated by the electromagnetic wave and the entire substrate needs not be heated. Thus, an increase of a processing time due to the heat capacity of the substrate can be suppressed.

Further, for example, the heater may include a heat radiating member controlled to have a temperature higher than the plate unit and a moving mechanism for moving the heat radiating member between a proximate position where the heat radiating member is proximately facing the upper surface of the plate unit and a separated position where the heat radiating member is more distant from the plate unit than at the proximate position. According to such a configuration, the sublimable substance can be quickly heated in a short time and sublimated by radiation heat from the heat radiating member heated in advance.

Further, for example, an ejector may be further provided which ejects the sublimated sublimable substance from an atmosphere of the substrate surface. According to such a configuration, it is possible to prevent the sublimable substance vaporized around the substrate from being accumulated and promote quick sublimation of the sublimable substance.

Further, for example, a rotator may be further provided which rotates the plate unit about a vertical axis. According to such a configuration, the sublimable substance adhering to the substrate surface can be evenly heated and the substrate can be uniformly processed.

Further, in the substrate processing system according to the invention, the liquid film forming unit may include a holder for holding the substrate in a horizontal posture in the first chamber and a liquid supplier for forming a liquid film by supplying a solution to the upper surface of the substrate. According to such a configuration, a liquid film of a desired thickness can be formed on the substrate upper surface by supplying a proper amount of the solution to the substrate held in the horizontal posture.

This invention can be applied to substrate processing method and apparatus for drying surfaces of substrates in general including semiconductor wafers, glass substrates for photo mask, glass substrates for liquid crystal display, substrates for plasma display, substrates for FED (Field Emission Display), substrates for optical disc, substrates for magnetic disc and substrates for opto-magnetic disc.

Although the invention has been described with reference to specific embodiments, this description is not meant to be construed in a limiting sense. Various modifications of the disclosed embodiment, as well as other embodiments of the present invention, will become apparent to persons skilled in the art upon reference to the description of the invention. It is therefore contemplated that the appended claims will cover any such modifications or embodiments as fall within the true scope of the invention.

What is claimed is:

1. A substrate processing apparatus, comprising:
a first chamber;
a liquid film former which forms a liquid film of a solution containing a sublimable substance having sublimability on a surface of a substrate in the first chamber;
a second chamber which receives the substrate having the liquid film formed thereon;
a plate unit which is provided in the second chamber such that the substrate is placeable on an upper surface thereof;
a temperature controller which controls a temperature of the upper surface of the plate unit to a predetermined temperature; and
a heater which heats and sublimates the sublimable substance precipitated from the solution on the substrate placed on the plate unit.

2. The substrate processing apparatus according to claim 1, wherein
the heater irradiates an electromagnetic wave for increasing the temperature of the sublimable substance toward the plate unit from above the plate unit.

3. The substrate processing apparatus according to claim 1, wherein the heater includes:
a heat radiating member which is controlled to have a temperature higher than the plate unit; and
a moving mechanism which moves the heat radiating member between a proximate position where the heat radiating member is proximately facing the upper surface of the plate unit and a separated position where the heat radiating member is more distant from the plate unit than at the proximate position.

4. The substrate processing apparatus according to claim 1, further comprising an ejector which ejects the sublimated sublimable substance from an atmosphere of the substrate surface.

5. The substrate processing apparatus according to claim 1, further comprising a rotator which rotates the plate unit about a vertical axis.

6. The substrate processing apparatus according to claim 1, further comprising a conveyor which conveys the substrate having the liquid film formed thereon from the first chamber to the second chamber.

7. The substrate processing apparatus according to claim 1, wherein the liquid film former includes:
a holder which holds the substrate in a horizontal posture in the first chamber; and
a liquid supplier supplies a solution to the upper surface of the substrate to form the liquid film.

8. A substrate processing apparatus, comprising:
a chamber which receives a substrate having a liquid film of a solution containing a sublimable substance having sublimability formed on a surface thereof;
a plate unit which is provided in the chamber such that the substrate is placeable on an upper surface thereof;
a temperature controller which controls a temperature of the upper surface of the plate unit to a predetermined temperature; and
a heater which heats and sublimates the sublimable substance precipitated from the solution on the substrate placed on the plate unit.

9. The substrate processing apparatus according to claim 8, wherein
the heater irradiates an electromagnetic wave for increasing the temperature of the sublimable substance toward the plate unit from above the plate unit.

10. The substrate processing apparatus according to claim 8, wherein the heater includes:
a heat radiating member which is controlled to have a temperature higher than the plate unit; and
a moving mechanism which moves the heat radiating member between a proximate position where the heat radiating member is proximately facing the upper surface of the plate unit and a separated position where the heat radiating member is more distant from the plate unit than at the proximate position.

11. The substrate processing apparatus according to claim 8, further comprising an ejector which ejects the sublimated sublimable substance from an atmosphere of the substrate surface.

12. The substrate processing apparatus according to claim 8, further comprising a rotator which rotates the plate unit about a vertical axis.

13. A substrate processing method, comprising:
forming a liquid film by a solution containing a sublimable substance having sublimability on a surface of a substrate in a first chamber;
conveying the substrate having the liquid film to a second chamber and placing the substrate on a plate unit which is provided in the second chamber and has an upper surface temperature-controlled to a predetermined temperature;
evaporating a solvent from the liquid film on the substrate placed on the plate unit and precipitating the sublimable substance in the second chamber; and
heating and sublimating the sublimable substance precipitated in the second chamber.
